(19) United States
(12) Patent Application Publication
(10) Pub. No.: US 2019/0029111 A1
(43) Pub. Date: Jan. 24, 2019

(54) METHOD FOR PRODUCING METAL WIRING-CONTAINING LAMINATE, METAL WIRING-CONTAINING LAMINATE, AND SUBSTRATE WITH PLATED LAYER

(71) Applicant: FUJIFILM Corporation, Tokyo (JP)

(72) Inventors: Chika MATSUOKA, Kanagawa (JP); Takahiko ICHIKI, Kanagawa (JP); Takehiro KASAHARA, Kanagawa (JP); Takeshi NARITA, Kanagawa (JP)

(73) Assignee: FUJIFILM Corporation, Tokyo (JP)

(21) Appl. No.: 16/131,121

(22) Filed: Sep. 14, 2018

Related U.S. Application Data
(63) Continuation of application No. PCT/JP2017/011332, filed on Mar. 22, 2017.

(30) Foreign Application Priority Data
Mar. 30, 2016 (JP) 2016-068253

(51) Int. Cl. H05K 1/02; H05K 3/18; H05K 3/46; B32B 15/01

(52) U.S. Cl. CPC H05K 1/0298; B32B 15/01; H05K 3/46; H05K 3/185

(57) ABSTRACT

The present invention provides a method for producing a metal wiring-containing laminate which is capable of efficiently producing a metal wiring-containing laminate having a fine metal wiring with low resistance; as well as a metal wiring-containing laminate and a substrate with a plated layer. The method for producing a metal wiring-containing laminate of the present invention includes: a step of forming a photosensitive layer having a functional group capable of interacting with a plating catalyst or a precursor thereof on a substrate; a step of exposing the photosensitive layer in a patternwise manner and subjecting the exposed photosensitive layer to a development treatment to form a plated layer having a groove portion; a step of applying a plating catalyst or a precursor thereof to the plated layer; and a step of subjecting the plated layer, to which the plating catalyst or the precursor thereof has been applied, to a plating treatment to form a metal wiring so as to fill the groove portion.

### CROSS-REFERENCE TO RELATED APPLICATIONS

This application is a Continuation of PCT International Application No. PCT/JP2017/011332 filed on Mar. 22, 2017, which claims priority under 35 U.S.C. § 119(a) to Japanese Patent Application No. 2016-068253 filed on Mar. 30, 2016. The above application is hereby expressly incorporated by reference, in its entirety, into the present application.

### BACKGROUND OF THE INVENTION

### 1. Field of the Invention

The present invention relates to a method for producing a metal wiring-containing laminate, a metal wiring-containing laminate, and a substrate with a plated layer.

### 2. Description of the Related Art

An electroconductive film (metal wiring-containing laminate) in which a metal wiring is disposed on a substrate is used for various applications such as a touch panel and a printed wiring board.

As a method for producing a metal wiring-containing laminate, for example, JP2015-57812A discloses an aspect using a non-curable resin layer. More specifically, JP2015-57812A discloses an aspect including a step of forming a non-curable resin layer on a surface of a substrate through a curable resin layer, a step of forming a concave portion on the non-curable resin layer and the curable resin layer from the non-curable resin layer side, a step of applying a plating catalyst onto the surface of the non-curable resin layer and the surface of the concave portion, a step of removing the non-curable resin layer together with the plating catalyst on the surface thereof, and a step of subjecting the surface of the concave portion to electroless plating.

### SUMMARY OF THE INVENTION

On the other hand, in recent years, it has been demanded to efficiently produce a metal wiring-containing laminate having a finer metal wiring.

According to the method described in JP2015-57812A, it is necessary to separately produce a non-curable resin layer, and there is a time and effort to remove it, so such a method has not necessarily satisfied the recent demands.

In view of the above-mentioned circumstances, an object of the present invention is to provide a method for producing a metal wiring-containing laminate which is capable of efficiently producing a metal wiring-containing laminate having a fine metal wiring with low resistance.

Another object of the present invention is to provide a metal wiring-containing laminate and a substrate with a plated layer.

As a result of extensive studies on the problems of the related art, the present inventors have found that the foregoing object can be achieved by using a plated layer having a groove portion.

That is, the present inventors have found that the foregoing object can be achieved by the following configuration.

(1) A method for producing a metal wiring-containing laminate, comprising:
a step of forming a photosensitive layer having a functional group capable of interacting with a plating catalyst or a precursor thereof on a substrate;
a step of exposing the photosensitive layer in a patternwise manner and subjecting the exposed photosensitive layer to a development treatment to form a plated layer having a groove portion;
a step of applying a plating catalyst or a precursor thereof to the plated layer; and
a step of subjecting the plated layer, to which the plating catalyst or the precursor thereof has been applied, to a plating treatment to form a metal wiring so as to fill the groove portion.

(2) The method for producing a metal wiring-containing laminate according to (1), in which the photosensitive layer is a negative tone photosensitive layer, and
the photosensitive layer is exposed through a photo mask having a light shielding portion having a width of 10 μm or less at the time of exposure.

(3) The method for producing a metal wiring-containing laminate according to (1) or (2), in which the photosensitive layer contains a compound having a functional group capable of interacting with a plating catalyst or a precursor thereof, and a compound having a polymerizable group.

(4) A metal wiring-containing laminate, comprising:
a substrate;
a plated layer disposed on the substrate and having a groove portion and a functional group capable of interacting with a plating catalyst or a precursor thereof; and
a metal wiring disposed so as to fill the groove portion of the plated layer,
in which metals are scattered in a surface (on a surface) of the plated layer opposite to the substrate side.

(5) The metal wiring-containing laminate according to (4), in which metals of the same type as the metals scattered on the surface of the plated layer opposite to the substrate side are scattered in a side wall surface (on a side wall surface) of the groove portion of the plated layer, and
the amount of the metals scattered on the side wall surface of the groove portion of the plated layer is larger than the amount of metals scattered on the surface of the plated layer opposite to the substrate side.

(6) A substrate with a plated layer, comprising:
a substrate; and
a plated layer disposed on the substrate and having a groove portion and a functional group capable of interacting with a plating catalyst or a precursor thereof.

According to the present invention, it is possible to provide a method for producing a metal wiring-containing laminate which is capable of efficiently producing a metal wiring-containing laminate having a fine metal wiring with low resistance.

Further, according to the present invention, it is also possible to provide a metal wiring-containing laminate and a substrate with a plated layer.

### BRIEF DESCRIPTION OF THE DRAWINGS

FIG. 1 is a cross-sectional view showing an aspect of Step A of a production method of the present invention.

FIG. 2 is a cross-sectional view showing an aspect of exposure in Step B of the production method of the present invention.

FIG. 3 is a cross-sectional view of a substrate with a plated layer obtained through a development treatment in Step B of the production method of the present invention.

FIG. 4 is a top view showing one aspect of a photo mask.

FIG. 5 is a cross-sectional view of a metal wiring-containing laminate obtained through Step D of the production method of the present invention.

### DESCRIPTION OF THE PREFERRED EMBODIMENTS

Hereinafter, the present invention will be described in detail.

Descriptions of the constituent features described below are sometimes made based on representative embodiments of the present invention, but the present invention is not limited to such embodiments.

Further, in the present specification, the numerical range expressed by using “to” means a range including numerical values described before and after “to” as a lower limit value and an upper limit value, respectively.

As will be described later in detail, a feature of the production method of the present invention is that a plated layer having a groove portion is used. In the case where a plating catalyst or a precursor thereof is adsorbed to such a plated layer, the plating catalyst or the precursor thereof is more likely to be adsorbed to the side wall surface of the groove portion than the surface of the plated layer opposite to the substrate side. Therefore, in the case where the obtained plated layer is subjected to a plating treatment, a metal wiring (plating layer) is formed so as to fill the groove portion. That is, it is possible to form a fine metal wiring with low resistance according to the size of the groove portion.

The method for producing a metal wiring-containing laminate of the present invention includes Steps A to D given below.

Step A: a step of forming a photosensitive layer having a functional group capable of interacting with a plating catalyst or a precursor thereof on a substrate

Step B: a step of exposing the photosensitive layer in a patternwise manner and subjecting the exposed photosensitive layer to a development treatment to form a plated layer having a groove portion

Step C: a step of applying a plating catalyst or a precursor thereof to the plated layer

Step D: a step of subjecting the plated layer, to which the plating catalyst or the precursor thereof has been applied, to a plating treatment to form a metal wiring so as to fill the groove portion

Hereinafter, materials used in each step and procedures thereof will be described in detail with reference to the accompanying drawings.

### Step A (Photosensitive Layer Forming Step)

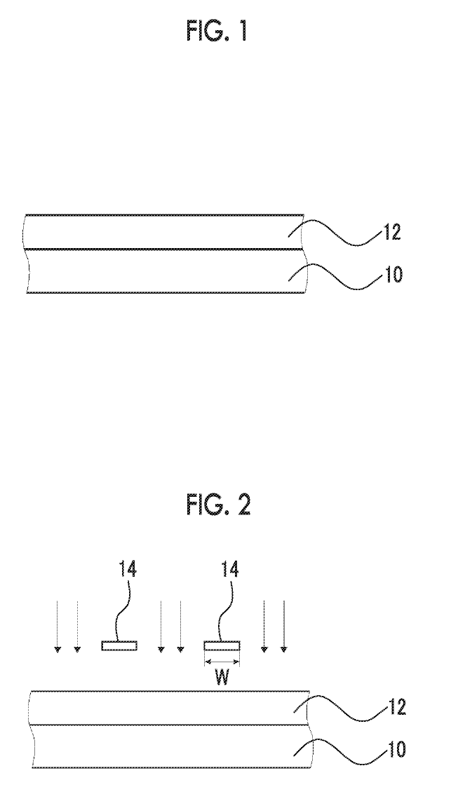

Step A is a step of forming a photosensitive layer having a functional group capable of interacting with a plating catalyst or a precursor thereof on a substrate. By carrying out the present step, as shown in FIG. 1, a photosensitive layer 12 is formed on a substrate 10. The photosensitive layer is a precursor layer for forming a plated layer having a groove portion (plated layer forming layer).

Hereinafter, first, each member and each material used in the present step will be described in detail, and then the procedure of the step will be described in detail.

### Substrate

There is no particular limitation on the type of the substrate as long as it can support a plated layer or the like which will be described later, and a known substrate can be used.

The substrate may be, for example, an insulating substrate, and more specific examples thereof include a resin substrate, a ceramic substrate, and a glass substrate.

Examples of the material for the resin substrate include a polyester-based resin (polyethylene terephthalate or polyethylene naphthalate), a polyethersulfone-based resin, a poly(meth)acrylic resin, a polyurethane-based resin, a polycarbonate-based resin, a polysulfone-based resin, a polyamide-based resin, a polyarylate-based resin, a polyolefin-based resin, a cellulose-based resin, a polyvinyl chloride-based resin, and a cycloolefin-based resin.

The thickness (mm) of the substrate is not particularly limited, but is preferably 0.005 to 1 mm and more preferably 0.02 to 0.08 mm from the viewpoint of the balance of handleability and thinning of the substrate.

Further, it is preferred that the substrate properly transmits light. Specifically, the total light transmittance of the substrate is preferably 85% to 100%.

In addition, an easily adhesive layer, a primer layer, or the like may be disposed on the substrate, if necessary. That is, a substrate with an easily adhesive layer, a substrate with a primer layer, or the like may be used.

### Photosensitive Layer

The photosensitive layer is a layer disposed on the substrate and is a layer for forming a plated layer having a groove portion.

The photosensitive layer has a functional group capable of interacting with a plating catalyst or a precursor thereof (hereinafter, also referred to as “interactive group”).

The interactive group is intended to refer to a functional group capable of interacting a plating catalyst or a precursor thereof which is applied to a plated layer. Examples of the interactive group include a functional group capable of forming an electrostatic interaction with a plating catalyst or a precursor thereof, or a nitrogen-, sulfur- or oxygen-containing functional group capable of coordinating with a plating catalyst and a precursor thereof.

More specific examples of the interactive group include nitrogen-containing functional groups such as an amino group, an amide group, an imido group, a urea group, a tertiary amino group, an ammonium group, an amidino group, a triazine ring, a triazole ring, a benzotriazole group, an imidazole group, a benzimidazole group, a quinoline group, a pyridine group, a pyrimidine group, a pyrazine group, a quinazoline group, a quinoxaline group, a purine group, a triazine group, a piperidine group, a piperazine group, a pyrrolidine group, a pyrazole group, an aniline group, a group containing an alkylamine structure, a group containing an isocyanuric structure, a nitro group, a nitroso group, an azo group, a diazo group, an azide group, a cyano group, and a cyanate group; oxygen-containing functional groups such as an ether group, a hydroxyl group, a phenolic hydroxyl group, a carboxylic acid group, a carbonate group, a carbonyl group, an ester group, a group containing an N-oxide structure, a group containing an S-oxide structure, and a group containing an N-hydroxy structure; sulfur-containing functional groups such as a thiophene group, a thiol group, a thiourea group, a thiocyanurate group, a benzothiazole group, a mercaptotriazine group, a thioether group, a thioxy group, a sulfoxide group, a sulfone group, a sulfite group, a group containing a sulfoximine structure, a group containing a sulfoxonium salt structure, a sulfonate group, and a group containing a sulfonic ester structure; phosphorus-containing functional groups such as a phosphate group, a phosphoramide group, a phosphine group, and a group containing a phosphoric ester structure; and a group containing a halogen atom such as a chlorine atom or a bromine atom. In a functional group that may have a salt structure, a salt thereof may also be used.

Among them, an ionic polar group such as a carboxylic acid group, a sulfonate group, a phosphate group or a boronate group, an ether group, or a cyano group is preferable, and a carboxylic acid group (carboxyl group) or a cyano group is more preferable, from the viewpoint of high polarity and high adsorptive capacity to a plating catalyst or a precursor thereof.

The photosensitive layer may be a negative tone photosensitive layer or a positive tone photosensitive layer. Among them, a negative tone photosensitive layer is preferable from the viewpoint that it is easier to form a finer metal wiring.

The negative tone photosensitive layer is a layer from which an unexposed portion is removed during development treatment. Further, the positive tone photosensitive layer is a layer from which an exposed portion is removed during development treatment.

In the case where the photosensitive layer is a negative tone photosensitive layer, it is preferred that the photosensitive layer has a polymerizable group together with the interactive group.

The polymerizable group is a functional group capable of forming a chemical bond through exposure, and examples thereof include a radically polymerizable group and a cationic polymerizable group. Among them, a radically polymerizable group is preferable from the viewpoint of superior reactivity. Examples of the radically polymerizable group include unsaturated carboxylic ester groups such as an acrylic ester group (acryloyloxy group), methacrylic ester group (methacryloyloxy group), an itaconic ester group, a crotonic ester group, an isocrotonic ester group, and a maleic ester group; a styryl group, a vinyl group, an acrylamide group, and an methacrylamide group. Among them, preferred is a methacryloyloxy group, an acryloyloxy group, a vinyl group, a styryl group, an acrylamide group, or methacrylamide group; and more preferred is a methacryloyloxy group, an acryloyloxy group, or a styryl group.

The photosensitive layer preferably contains Compound X or Composition Y below, from the viewpoint that it is easier to form a finer metal wiring.

Compound X: a compound having an interactive group and a polymerizable group

Composition Y: a composition containing a compound having an interactive group and a compound having a polymerizable group

### Compound X

Compound X is a compound having an interactive group and a polymerizable group. The definitions of the interactive group and the polymerizable group are as described above.

Compound X may contain two or more interactive groups. The number of interactive groups contained in Compound X is not particularly limited, and may be one or may be two or more.

Compound X may contain two or more polymerizable groups. The number of polymerizable groups contained in Compound X is not particularly limited, and may be one or may be two or more.

Compound X may be a low molecular weight compound or a high molecular weight compound. The low molecular weight compound is intended to refer to a compound having a molecular weight of less than 1,000, and the high molecular weight compound is intended to refer to a compound having a molecular weight of 1,000 or more.

Further, the low molecular weight compound having a polymerizable group corresponds to a so-called monomer. Further, the high molecular weight compound may be a polymer having a predetermined repeating unit.

Further, the compounds may be used alone or in combination of two or more thereof.

In the case where Compound X is a polymer, the weight-average molecular weight of the polymer is not particularly limited and is preferably 1,000 to 700,000 and more preferably 2,000 to 200,000, from the viewpoint that handleability such as solubility is superior. In particular, the weight-average molecular weight of the polymer is preferably 20,000 or more from the viewpoint of polymerization sensitivity.

The method of synthesizing a polymer having a polymerizable group and an interactive group is not particularly limited and a known synthesis method (see paragraphs [0097] to [0125] of JP2009-280905A) is used.

### Suitable Aspect 1 of Polymer

In the case where Compound X is a polymer, a first preferred aspect of the polymer may be, for example, a copolymer containing a polymerizable group-containing repeating unit represented by Formula (a) (hereinafter, also referred to as a “polymerizable group unit” where appropriate) and an interactive group-containing repeating unit represented by Formula (b) (hereinafter, also referred to as an “interactive group unit” where appropriate).

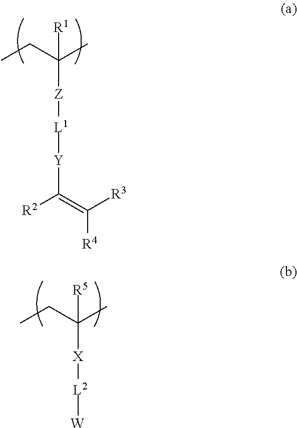

In Formulae (a) and (b), R¹ to R⁵ each independently represent a hydrogen atom, or a substituted or unsubstituted alkyl group (for example, a methyl group, an ethyl group, a propyl group, or a butyl group). Further, the type of the substituent is not particularly limited, and examples thereof include a methoxy group, a chlorine atom, a bromine atom, and a fluorine atom.

R¹ is preferably a hydrogen atom, a methyl group, or a methyl group substituted with a bromine atom. R² is preferably a hydrogen atom, a methyl group, or a methyl group substituted with a bromine atom. R³ is preferably a hydrogen atom. R⁴ is preferably a hydrogen atom. R⁵ is preferably a hydrogen atom, a methyl group, or a methyl group substituted with a bromine atom.

In Formulae (a) and (b), X, Y, and Z each independently represent a single bond, or a substituted or unsubstituted divalent organic group. Examples of the divalent organic group include a substituted or unsubstituted divalent aliphatic hydrocarbon group (which preferably contains 1 to 8 carbon atoms. For example, an alkylene group such as a methylene group, an ethylene group, or a propylene group), a substituted or unsubstituted divalent aromatic hydrocarbon group (which preferably contains 6 to 12 carbon atoms. For example, a phenylene group), —O—, —S—, —SO₂—, —N(R)—(R: alkyl group), —CO—, —NH—, —COO—, —CONH—, and a group formed by combining these groups (for example, an alkyleneoxy group, an alkyleneoxycarbonyl group, or an alkylenecarbonyloxy group).

X, Y, and Z are each preferably a single bond, an ester group (—COO—), an amide group (—CONH—), an ether group (—O—), or a substituted or unsubstituted divalent aromatic hydrocarbon group and more preferably a single bond, an ester group (—COO—), or an amide group (—CONH—), from the viewpoint of easy polymer synthesis and superior adhesiveness between the plated layer and the metal wiring.

In Formulae (a) and (b), L¹ and L² each independently represent a single bond, or a substituted or unsubstituted divalent organic group. The divalent organic group has the same definition as in the divalent organic group described for X, Y, and Z above.

L¹ is preferably a divalent aliphatic hydrocarbon group or a divalent organic group (for example, an aliphatic hydrocarbon group) having a urethane bond or a urea bond from the viewpoint of easy polymer synthesis and superior adhesiveness between the plated layer and the metal wiring. The total number of carbon atoms contained in L¹ is preferably 1 to 9. Here, the total number of carbon atoms in L¹ refers to the total number of carbon atoms contained in the substituted or unsubstituted divalent organic group represented by L¹.

Further, L² is preferably a single bond, a divalent aliphatic hydrocarbon group, a divalent aromatic hydrocarbon group, or a group formed by combining these groups, from the viewpoint of superior adhesiveness between the plated layer and the metal wiring. Among them, L² is preferably a single bond or a substituted or unsubstituted divalent organic group having a total number of carbon atoms of 1 to 15. Here, the total number of carbon atoms in L² refers to a total number of carbon atoms contained in the substituted or unsubstituted divalent organic group represented by L². The divalent organic group represented by L² is preferably unsubstituted.

In Formula (b), W represents an interactive group. The definition of the interactive group is as described above.

The content of the polymerizable group unit is preferably 5 to 60 mol % and more preferably 5 to 40 mol % with respect to the total repeating units in the polymer, from the viewpoint of reactivity (curability or polymerizability) and inhibition of gelation during synthesis.

Further, the content of the interactive group unit is preferably 5 to 95 mol % and more preferably 10 to 95 mol % with respect to the total repeating units in the polymer, from the viewpoint of adsorptivity to a plating catalyst or a precursor thereof.

### Suitable Aspect 2 of Polymer

In the case where Compound X is a polymer, the second preferred aspect of the polymer may be, for example, a copolymer containing repeating units represented by Formula (A), Formula (B), and Formula (C).

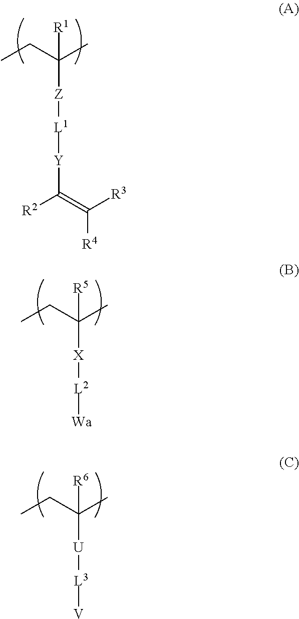

The repeating unit represented by Formula (A) is the same as the repeating unit represented by Formula (a), and the same also applies to the description of each group.

R⁵, X, and L² in the repeating unit represented by Formula (B) is the same as R⁵, X, and L² in the repeating unit represented by Formula (b), and the same also applies to the description of each group.

Wa in Formula (B) represents a group capable of interacting with a plating catalyst or a precursor thereof, excluding a hydrophilic group or a precursor group thereof represented by V to be described hereinafter. Among them, preferred is a cyano group.

In Formula (C), R⁶'s each independently represent a hydrogen atom or a substituted or unsubstituted alkyl group.

In Formula (C), U represents a single bond or a substituted or unsubstituted divalent organic group. The definition of the divalent organic group is the same as that of the above-mentioned divalent organic group represented by X, Y, and Z. U is preferably a single bond, an ester group (—COO—), an amide group (—CONH—), an ether group (—O—), or a substituted or unsubstituted divalent aromatic hydrocarbon group, from the viewpoint of easy polymer synthesis and superior adhesiveness between the plated layer and the metal wiring.

In Formula (C), L³ represents a single bond or a substituted or unsubstituted divalent organic group. The definition of the divalent organic group is the same as that of the above-mentioned divalent organic group represented by L¹ and L². L³ is preferably a single bond, or a divalent aliphatic hydrocarbon group, a divalent aromatic hydrocarbon group, or a group formed by combining these groups, from the viewpoint of easy polymer synthesis and superior adhesiveness between the plated layer and the metal wiring.

In Formula (C), V represents a hydrophilic group or a precursor group thereof. The hydrophilic group is not particularly limited as long as it is a group exhibiting hydrophilicity, and examples thereof include a hydroxyl group and a carboxylic acid group. The precursor group of the hydrophilic group refers to a group capable of generating a hydrophilic group by a predetermined treatment (for example, treatment with an acid or alkali), and examples thereof include a carboxylic acid group protected with a 2-tetrahydropyranyl (THP) group.

The hydrophilic group is preferably an ionic polar group from the viewpoint of interaction with a plating catalyst or a precursor thereof. Examples of the ionic polar group include a carboxylic acid group, a sulfonate group, a phosphate group, and a boronate group. Among them, preferred is a carboxylic acid group from the viewpoint of moderate acidity (not degrading other functional groups).

The preferred content of each unit in the second preferred aspect of the polymer is as follows.

The content of the repeating unit represented by Formula (A) is preferably 5 to 50 mol % and more preferably 5 to 30 mol % with respect to the total repeating units in the polymer, from the viewpoint of reactivity (curability or polymerizability) and inhibition of gelation during synthesis.

The content of the repeating unit represented by Formula (B) is preferably 5 to 75 mol % and more preferably 10 to 70 mol % with respect to the total repeating units in the polymer, from the viewpoint of adsorptivity of a plating catalyst or a precursor thereof to a plated layer.

The content of the repeating unit represented by Formula (C) is preferably 10 to 70 mol %, more preferably 20 to 60 mol %, and still more preferably 30 to 50 mol % with respect to the total repeating units in the polymer, from the viewpoint of developability of the photosensitive layer with an aqueous solution and humidity-resistant adhesiveness of the plated layer.

Specific examples of the above-mentioned polymer include polymers described in paragraphs [0106] to [0112] of JP2009-007540A, polymers described in paragraphs [0065] to [0070] of JP2006-135271A, and polymers described in paragraphs [0030] to [0108] of U.S.2010-080964A.

These polymers can be produced by known methods (for example, methods in the literature listed above).

### Suitable Aspect of Monomer

In the case where Compound X is a so-called monomer, a compound represented by Formula (X) can be mentioned as one suitable aspect of the monomer.

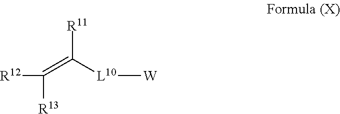

In Formula (X), R¹¹ to R¹³ each independently represent a hydrogen atom or a substituted or unsubstituted alkyl group. Examples of the unsubstituted alkyl group include a methyl group, an ethyl group, a propyl group, and a butyl group. Examples of the substituted alkyl group include a methyl group, an ethyl group, a propyl group, and a butyl group each of which is substituted with a methoxy group, a chlorine atom, a bromine atom, a fluorine atom, or the like. R¹¹ is preferably a hydrogen atom or a methyl group. R¹² is preferably a hydrogen atom. R¹³ is preferably a hydrogen atom.

L¹⁰ represents a single bond or a divalent organic group. Examples of the divalent organic group include a substituted or unsubstituted aliphatic hydrocarbon group (preferably having 1 to 8 carbon atoms), a substituted or unsubstituted aromatic hydrocarbon group (preferably having 6 to 12 carbon atoms), —O—, —S—, —SO₂—, —N(R)— (R: alkyl group), —CO—, —NH—, —COO—, —CONH—, and a group formed by combining these groups (for example, an alkyleneoxy group, an alkyleneoxycarbonyl group, or an alkylenecarbonyloxy group).

The substituted or unsubstituted aliphatic hydrocarbon group is preferably a methylene group, an ethylene group, a propylene group or a butylene group, or a group in which such a group is substituted with a methoxy group, a chlorine atom, a bromine atom, a fluorine atom, or the like.

The substituted or unsubstituted aromatic hydrocarbon group is preferably an unsubstituted phenylene group, or a phenylene group substituted with a methoxy group, a chlorine atom, a bromine atom, a fluorine atom, or the like.

In Formula (X), one suitable aspect of L¹⁰ may be, for example, a —NH-aliphatic hydrocarbon group— or a —CO-aliphatic hydrocarbon group—.

W has the same definition as W in Formula (b) and represents an interactive group.

In Formula (X), a suitable aspect of W may be, for example, an ionic polar group and is more preferably a carboxylic acid group.

### Composition Y

The composition Y is a composition containing a compound having an interactive group and a compound having a polymerizable group. That is, the photosensitive layer contains two compounds: a compound having an interactive group and a compound having a polymerizable group. The definition of the interactive group and the polymerizable group is as described above.

The compound having an interactive group may be a low molecular weight compound or a high molecular weight compound. Among others, a polymer having an interactive group is preferable.

A suitable aspect of the compound having an interactive group may be, for example, a polymer having a repeating unit represented by Formula (b) as described above (for example, polyacrylic acid). Further, it is preferred that the compound having an interactive group does not contain a polymerizable group.

The compound having a polymerizable group is a so-called monomer, and is preferably a polyfunctional monomer having two or more polymerizable groups from the viewpoint of superior hardness of a plated layer which will be formed. Specifically, the polyfunctional monomer is preferably a monomer having 2 to 6 polymerizable groups. From the viewpoint of mobility of molecules during the crosslinking reaction which affects the reactivity, the molecular weight of the polyfunctional monomer to be used is preferably 150 to 1,000 and more preferably 200 to 700. Further, the interval (distance) between a plurality of polymerizable groups is preferably 1 to 15 and more preferably 6 to 10 in terms of the number of atoms.

The compound having a polymerizable group may contain an interactive group.

A suitable aspect of the compound having a polymerizable group may be, for example, a compound represented by Formula (1).

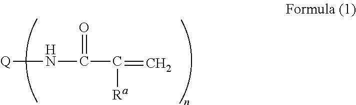

In Formula (1), Q represents an n-valent linking group, and R^{a} represents a hydrogen atom or a methyl group. n represents an integer of 2 or more.

R^{a} represents a hydrogen atom or a methyl group, and preferably a hydrogen atom.

The valence n of Q is 2 or more, and is preferably 2 to 6, more preferably 2 to 5, and still more preferably 2 to 4 from the viewpoint of further improving the adhesiveness between the plated layer and the metal wiring.

Examples of the n-valent linking group represented by Q include a group represented by Formula (1A), a group represented by Formula (1B),

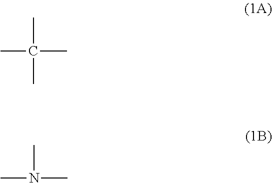

—NH—, —NR (where R represents an alkyl group)—, —O—, —S—, a carbonyl group, an alkylene group, an alkenylene group, an alkynylene group, a cycloalkylene group, an aromatic group, a heterocyclic group, and a group formed by combining two or more of these groups.

A suitable aspect of the compound represented by Formula (1) may be, for example, a compound represented by Formula (Y).

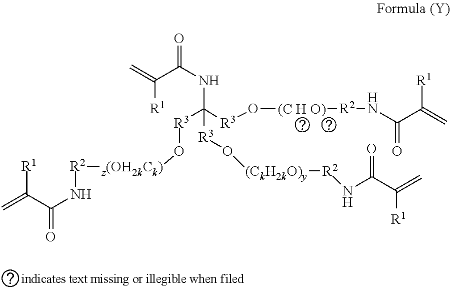

In Formula (Y), R¹'s each independently represent a hydrogen atom or a methyl group. R²'s each independently represent a linear or branched alkylene group having 2 to 4 carbon atoms, provided that R² does not have a structure in which the oxygen atom and the nitrogen atom bonded to both ends of R² are bonded to the same carbon atom of R². R³'s each independently represent a divalent linking group. k represents 2 or 3. x, y, and z each independently represent an integer of 0 to 6, and x+y+z satisfies 0 to 18.

R² represents a linear or branched alkylene group having 2 to 4 carbon atoms. The plurality of R²'s may be the same as or different from each other. R² is preferably an alkylene group having 3 or 4 carbon atoms, more preferably an alkylene group having 3 carbon atoms, and still more preferably a linear alkylene group having 3 carbon atoms. The alkylene group of R² may further have a substituent, and examples of the substituent include an aryl group or an alkoxy group.

However, R² does not have a structure in which the oxygen atom and the nitrogen atom bonded to both ends of R² are bonded to the same carbon atom of R². R² is a linear or branched alkylene group linking the oxygen atom and the nitrogen atom of the (meth)acrylamide group, and in the case where the alkylene group has a branched structure, it is also conceivable that R² has an —O—C—N-structure (hemiaminal structure) in which the oxygen atom and the nitrogen atom of the (meth)acrylamide group at the both ends thereof are bonded to the same carbon atom in the alkylene group. However, a compound having such a structure is not encompassed by the compound represented by Formula (Y).

Examples of the divalent linking group of R³ include an alkylene group, an arylene group, a heterocyclic group, and a group formed of a combination thereof, among which an alkylene group is preferable. In the case where the divalent linking group contains an alkylene group, the alkylene group may further contain at least one group selected from —O—, —S—, and NR^{b}—.

R^{b} represents a hydrogen atom or an alkyl group having 1 to 4 carbon atoms.

x, y, and z each independently represent an integer of 0 to 6, preferably an integer of 0 to 5, and more preferably an integer of 0 to 3. x+y+z satisfies 0 to 18, preferably 0 to 15, and more preferably 0 to 9.

The mass ratio of the compound having an interactive group and the compound having a polymerizable group (mass of the compound having an interactive group/mass of the compound having a polymerizable group) is not particularly limited, but it is preferably 0.1 to 10 and more preferably 0.5 to 5 in terms of balance of strength of a plated layer to be formed and plating suitability. From the viewpoint of obtaining a plated layer which shows good permeability, the mass ratio is preferably 0.5 to 1.

The content of Compound X (or Composition Y) in the photosensitive layer is not particularly limited, but it is preferably 50% by mass or more and more preferably 80% by mass or more with respect to the total mass of the photosensitive layer. The upper limit thereof is not particularly limited, but it is preferably 99.5% by mass or less.

The photosensitive layer may contain components other than Compound X and Composition Y described above.

The photosensitive layer may contain a polymerization initiator. By including the polymerization initiator, the reaction between the polymerizable groups during the exposure treatment more efficiently proceeds.

The polymerization initiator is not particularly limited, and a known polymerization initiator (so-called photopolymerization initiator) or the like can be used. Examples of the polymerization initiator include benzophenones, acetophenones, α-aminoalkylphenones, benzoins, ketones, thioxanthones, benzyls, benzyl ketals, oxime esters, anthrones, tetramethylthiuram monosulfides, bisacylphosphine oxides, acylphosphine oxides, anthraquinones, azo compounds, and derivatives thereof.

The content of the polymerization initiator in the photosensitive layer is not particularly limited, but from the viewpoint of the curability of the plated layer, the content of the polymerization initiator is preferably 0.01% to 1% by mass and more preferably 0.1% to 0.5% by mass with respect to the total mass of the photosensitive layer.

The photosensitive layer may contain other additives (for example, a sensitizer, a curing agent, a polymerization inhibitor, an antioxidant, an antistatic agent, a filler, a particle, a flame retardant, a surfactant, a lubricant, and a plasticizer).

The thickness of the photosensitive layer is not particularly limited, but it is preferably 0.01 to 20 μm, more preferably 0.1 to 10 μm, and still more preferably 0.1 to 5 μm.

The above-mentioned thickness of the photosensitive layer is an average thickness, which is a value obtained by measuring thicknesses at 10 points of the photosensitive layer and arithmetically averaging the measured values.

### Procedure of Step

A method of forming a photosensitive layer on a substrate is not particularly limited, and examples thereof include a method in which a composition containing the above-mentioned various components (a plated layer forming composition) is applied onto a substrate to form a photosensitive layer (a coating method), and a method in which a photosensitive layer is formed on a temporary substrate and is then transferred onto a substrate (transfer method). Among them, a coating method is preferable from the viewpoint of easily controlling the thickness.

Hereinafter, aspects of the coating method will be described in detail.

The composition used in the coating method contains the above-mentioned components (for example, Compound X or Composition Y).

Further, the composition preferably contains a solvent, from the viewpoint of handleability.

The type of the solvent is not particularly limited, and examples thereof include water, an alcohol-based solvent, a ketone-based solvent, an amide-based solvent, a nitrile-based solvent, an ester-based solvent, a carbonate-based solvent, an ether-based solvent, a glycol-based solvent, an amine-based solvent, a thiol-based solvent, and a halogen-based solvent.

The content of the solvent in the composition is not particularly limited, but it is preferably 50% to 98% by mass and more preferably 70% to 95% by mass, with respect to the total amount of the composition. Within the above range, handleability of the composition is excellent and therefore the layer thickness of the photosensitive layer can be easily controlled.

In the case of the coating method, the method of applying the composition onto the substrate is not particularly limited, and a known method (for example, spin coating, die coating, or dip coating) can be used.

From the viewpoint of handleability of the composition and production efficiency of the photosensitive layer, an aspect of forming a photosensitive layer by applying the composition onto a substrate, and carrying out a drying treatment as necessary to remove the solvent remaining in the coating film is preferable.

The conditions of the drying treatment are not particularly limited, but from the viewpoint of superior productivity, it is preferable to carry out the drying treatment at room temperature to 220° C. (preferably 50° C. to 120° C.) for 1 to 30 minutes (preferably 1 to 10 minutes).

### Step B (Plated Layer Forming Step B)

Step B is a step of exposing the photosensitive layer in a patternwise manner and subjecting the exposed photosensitive layer to a development treatment to form a plated layer having a groove portion.

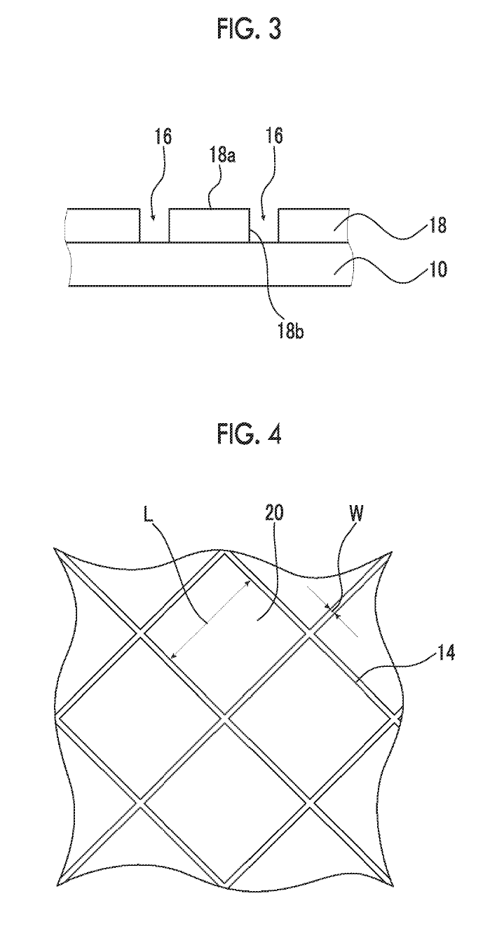

For example, in the case where the photosensitive layer is a negative tone photosensitive layer (for example, in the case where the photosensitive layer contains Compound X or Composition Y), first, as shown in FIG. 2, the photosensitive layer 12 is subjected to patternwise exposure through a photo mask having a predetermined light shielding portion 14. Next, the exposed photosensitive layer is subjected to a development treatment, whereby the unexposed portion is removed and therefore a plated layer 18 having a groove portion 16 is formed as shown in FIG. 3.

In FIG. 3, two groove portions are formed, but the number thereof is not particularly limited.

In the above description, the case where the photosensitive layer is a negative tone photosensitive layer has been described, but the present invention is not limited to this aspect. That is, a positive tone photosensitive layer may be used as the photosensitive layer. In the case of using a positive tone photosensitive layer, the exposed portion is removed and therefore a plated layer having a groove portion is formed.

In the case of forming the groove portion 16 as described above, the portion of the photosensitive layer immediately under the edge portion of the light shielding portion 14 is hardly exposed. As a result, in FIG. 3, the curing on the side wall surface 18b of the groove portion 16 is less likely to proceed than the curing on the surface 18a (the upper surface of the plated layer) of the plated layer 18 opposite to the substrate 10 side. Therefore, in the case where the plated layer 18 having the groove portion 16 comes into contact with a solution, the degree of curing of the side wall surface 18b portion of the groove portion 16 is low, so that the side wall surface 18b portion of the groove portion 16 is more likely to swell.

In the case where the photosensitive layer contains Composition Y as described above, the polymerization of a compound having a polymerizable group is difficult to proceed on the side wall surface 18b portion of the groove portion 16. Therefore, in the case where the development treatment is carried out, components derived from the compound having a polymerizable group elute more and therefore the concentration of a compound having an interactive group is further increased. That is, the concentration of the interactive group on the side wall surface 18b of the groove portion 16 is higher than the concentration of the interactive group on the surface 18a of the plated layer 18.

In the case where such a phenomenon occurs, a plating catalyst or a precursor thereof is preferentially adsorbed on the side wall surface 18b portion of the groove portion 16 in the case where the plating catalyst or the precursor thereof is applied to a plated layer having a groove portion. That is, the amount of the plating catalyst or the precursor thereof adsorbed on the side wall surface 18b of the groove portion 16 is larger than the amount of the plating catalyst or the precursor thereof adsorbed on the surface 18a of the plated layer 18. Therefore, in the case where such a plated layer is subjected to a plating treatment, plating is preferentially deposited in the groove portion, and as a result, a metal wiring is formed so as to fill the inside of the groove portion.

Hereinafter, the method of the exposure treatment will be described in detail and then the development treatment will be described in detail.

In the exposure treatment (light irradiation treatment), exposure with light having an optimum wavelength is carried out according to the material of the photosensitive layer to be used. For example, light irradiation with ultraviolet light, visible light, or the like is carried out. Examples of the light source include a mercury lamp, a metal halide lamp, a xenon lamp, a chemical lamp, and a carbon arc lamp. Further, electron beams, X-rays, ion beams, far infrared rays, or the like can also be used.

The exposure time varies depending on the reactivity of the material of the photosensitive layer and the light source, but it is usually between 10 seconds and 5 hours. The exposure energy may be about 10 to 10,000 mJ and preferably 2,000 to 10,000 mJ.

The method of carrying out the exposure in a patternwise manner is not particularly limited, and a known method is adopted. For example, the photosensitive layer may be irradiated with light through a photo mask having a predetermined opening portion (opening portion pattern).

The aspect of the photo mask to be used is not particularly limited, but in the case where the photosensitive layer is a negative tone photosensitive layer, it is preferable to use a photo mask having a light shielding portion having a width of 10 μm or less. The width of the light shielding portion is preferably 5 μm or less and more preferably 2 μm or less. The lower limit thereof is not particularly limited, but it is often 0.5 μm or more in many cases.

It should be noted that the width of the light shielding portion is intended to refer to, for example, W shown in FIG. 2 and W shown in FIG. 4.

At the time of exposure, it is preferable to carry out the exposure in a state where the photo mask is in close contact with the photosensitive layer (preferably a negative tone photosensitive layer). In the case where the exposure is carried out in a state where the photo mask is at a position distant from the surface of the photosensitive layer, a groove to be formed tends to become shallow due to spreading of the diffracted light, and as a result, the resistance of the metal wiring tends to rise.

Further, the shape of the light shielding portion in the photo mask is also not particularly limited, and can be appropriately selected according to the pattern of the groove portion.

For example, in the case where the photosensitive layer is a negative tone photosensitive layer and a mesh pattern-like groove portion is formed, it is preferable to use a photo mask having a light shielding portion 14 in a mesh pattern shape as shown in FIG. 4. In the case of a mesh pattern-like photo mask, the length L of one side of a lattice 20 (opening portion) in the mesh pattern is preferably 800 μm or less and more preferably 600 μm or less and is preferably 20 μm or more and more preferably 40 μm or more.

The shape of the lattice is not particularly limited, and it may be a substantially diamond shape or a polygonal shape (for example, triangle, quadrangle, or hexagon). Further, the shape of one side of the lattice may be a curved shape or an arc shape, in addition to the linear shape.

The percentage of the area of the light shielding portion in the photo mask (positive mask) used in the case where the photosensitive layer is a negative tone photosensitive layer is not particularly limited, but it is preferably 50% or less and more preferably 30% or less from the viewpoint of obtaining a finer metal wiring. The upper limit thereof is not particularly limited, but it is often 2.5% or more in many cases.

The percentage (%) of the area of the light shielding portion can be obtained by {(area of light shielding portion)/(area of light shielding portion+area of opening portion)}×100.

Next, the exposed photosensitive layer is subjected to a development treatment to form a plated layer having a groove portion.

The method of the development treatment is not particularly limited, and a known method can be adopted. For example, in the case where the photosensitive layer is a negative tone photosensitive layer, a method in which a solvent in which the photosensitive layer in the unexposed portion is soluble is brought into contact with the photosensitive layer can be mentioned. More specifically, there is a method using water as a developer. In the case of removing the unexposed portion using water, there are, for example, a method of immersing the substrate having the photosensitive layer subjected to the exposure treatment in water (immersion method), a method of applying water onto the photosensitive layer (a coating method), and a method of spraying water onto the photosensitive layer (spraying method), among which the spraying method is preferable. In the case of the spraying method, the spraying time is preferably about 1 to 30 minutes in terms of productivity and workability.

In the above description, water is used as a developer, but the developer is not limited to this aspect, and other developers (for example, an alkaline solution) or the like may be used.

Through the above treatment, a substrate with a plated layer, which includes a substrate and a plated layer disposed on the substrate and having a groove portion and an interactive group, is obtained.

The width of the groove portion is not particularly limited, but it is preferably 10 μm or less, more preferably 5 μm or less, and still more preferably 2 μm or less from the viewpoint of forming a finer metal wiring. The lower limit thereof is not particularly limited, but it is often 0.001 μm or more in many cases.

The depth of the groove portion is not particularly limited, but it is preferably 1/10 or more of the thickness of the plated layer and more preferably the same as the thickness of the plated layer. In other words, it is preferable to form a groove portion in the plated layer so that the substrate surface is exposed.

The pattern shape of the groove portion is not particularly limited. For example, as described above, in the case where a photo mask having a light shielding portion in the mesh pattern shape is used, a mesh-like groove portion can be formed.

### Step C (Plating Catalyst Applying Step C)

Step C is a step of applying a plating catalyst or a precursor thereof to the plated layer having a groove portion obtained in Step B. The interactive group contained in the plated layer adheres to (adsorbs) the applied plating catalyst or precursor thereof depending on the function thereof. As described above, by carrying out the present step, more plating catalyst or precursor thereof is applied to the side wall surface of the groove portion than the surface of the plated layer.

The plating catalyst or the precursor thereof functions as a catalyst and an electrode of the plating treatment. Therefore, the type of the plating catalyst or the precursor thereof to be used is appropriately determined depending on the type of the plating treatment.

Further, the plating catalyst or the precursor thereof is preferably an electroless plating catalyst or a precursor thereof. Hereinafter, mainly, an electroless plating catalyst or a precursor thereof will be described in detail.

The electroless plating catalyst is not particularly limited as long as it becomes an active nucleus at the time of electroless plating. Specifically, a metal having a catalytic capacity of the autocatalytic reduction reaction (for example, a metal which is known as a metal capable of electroless plating with lower ionization tendency than Ni) may be mentioned. More specific examples thereof include Pd, Ag, Cu, Pt, Au, and Co. Among them, preferred is Ag, Pd, Pt, or Cu from the viewpoint of high catalytic capacity.

A metallic colloid may be used as the electroless plating catalyst.

The electroless plating catalyst precursor is not particularly limited as long as it may be converted into an electroless plating catalyst by a chemical reaction. Ions of the metals illustrated above for the electroless plating catalyst are used. The metal ions which are the electroless plating catalyst precursors are converted by the reduction reaction into zero-valent metals which are the electroless plating catalysts. After the metal ion as the electroless plating catalyst precursor is applied to the plated layer, the electroless plating catalyst precursor may be converted into a zero-valent metal as the electroless plating catalyst by a separate reduction reaction before being immersed in an electroless plating bath. Alternatively, the electroless plating catalyst precursor may be immersed in the electroless plating bath without any treatment to be converted into a metal (electroless plating catalyst) by the action of a reducing agent in the electroless plating bath.

It is preferred that the type of the metal used as the plating catalyst or the precursor thereof is different from that of the metal deposited by the plating treatment to be described later.

A metal salt is preferably used to apply the metal ion as the electroless plating catalyst precursor to the plated layer. The metal salt is not particularly limited as long as it dissolves in a suitable solvent to be dissociated into a metal ion and a base (anion). Examples thereof include M(NO₃)ₙ, MClₙ, M_{2/n}(SO₄), and M_{3/n}(PO₄) (where M represents an n-valent metal atom). The metal ion resulting from the dissociation of the metal salt may be suitably used. Examples of the metal ion include Ag ion, Cu ion, Ni ion, Co ion, Pt ion, and Pd ion. Among them, metal ions capable of multidentate coordination are preferred. Particularly, Ag ion, Pd ion, or Cu ion is more preferred from the viewpoint of the number of types of functional groups capable of coordination and the catalytic capacity.

In the present step, a zero-valent metal may be used as the catalyst used for carrying out direct electroplating without electroless plating.

As a method of applying a plating catalyst or a precursor thereof to the plated layer, there is, for example, a method in which a plating catalyst or a precursor thereof is dispersed or dissolved in a suitable solvent to prepare a catalyst-applying solution and the solution is applied onto the plated layer, or a method in which a substrate having a plated layer is immersed in such a solution. The solvent may be, for example, water or an organic solvent.

The pH of the catalyst-applying solution is not particularly limited, but it is preferably acidic and more preferably 1 to 5.

The concentration of the plating catalyst or the precursor thereof in the catalyst-applying solution is not particularly limited, but it is preferably 0.001% to 50% by mass and more preferably 0.005% to 30% by mass.

The contact time between the plated layer and the catalyst-applying solution is preferably about 30 seconds to 24 hours and more preferably about 1 minute to 1 hour.

The amount of the plating catalyst or the precursor thereof adsorbed in the plated layer varies depending on a plating bath species to be used, a catalyst metal species, an interactive group species of a plated layer, usage, and the like, but it is preferably 5 to 1,000 mg/m², more preferably 10 to 800 mg/m², and still more preferably 20 to 600 mg/m² from the viewpoint of deposition property of plating.

### Step D (Plating Treatment Step)

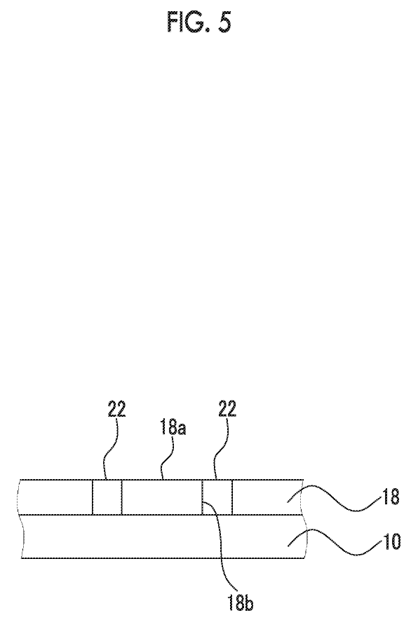

Step D is a step of subjecting the plated layer, to which the plating catalyst or the precursor thereof has been applied, to a plating treatment to form a metal wiring so as to fill the groove portion. By carrying out the present step, a metal wiring 22 shown in FIG. 5 is formed so as to fill the groove portion 16 of FIG. 3.

The method of a plating treatment is not particularly limited, and examples thereof include an electroless plating treatment and an electrolytic plating treatment (electroplating treatment). In the present step, an electroless plating treatment may be carried out alone, or an electrolytic plating treatment may be further carried out following an electroless plating treatment.

Hereinafter, the procedure of the electroless plating treatment and electrolytic plating treatment will be described in detail.

The electroless plating treatment is a treatment of depositing metals through a chemical reaction using a solution of metal ions to be deposited as plating dissolved therein.

For example, the electroless plating is preferably carried out in such a manner that a substrate having a plated layer to which an electroless plating catalyst has been applied is washed with water to remove an excess of the electroless plating catalyst (metal), and then the washed substrate is immersed in an electroless plating bath. As the electroless plating bath to be used, a known electroless plating bath may be employed.

Further, in the case where a substrate having a plated layer to which an electroless plating catalyst precursor has been applied is immersed in an electroless plating bath in a state of an electroless plating catalyst precursor being adsorbed or impregnated in the plated layer, it is preferred that a substrate is washed with water to remove an excess of the electroless plating catalyst precursor (such as a metal salt), and then the washed substrate is immersed in the electroless plating bath. In this case, the reduction of the electroless plating catalyst precursor and subsequently the electroless plating are carried out in the electroless plating bath. Also with respect to the electroless plating bath used herein, a known electroless plating bath may be employed in the same manner as described above.

Further, apart from the aspect of using an electroless plating liquid as described above, the reduction of an electroless plating catalyst precursor can also be carried out with the preparation of a catalyst activating liquid (reducing liquid), as a separate step prior to electroless plating.

Typically, the electroless plating bath mainly includes 1. metal ions for plating, 2. reducing agent, and 3. additive (stabilizer) that improves the stability of metal ions in addition to a solvent (for example, water). In addition to these components, the plating bath may include a known additive such as a stabilizer for a plating bath.

As the organic solvent used for the electroless plating bath, a solvent which is soluble in water is preferable; and ketones such as acetone and alcohols such as methanol, ethanol, and isopropanol are more preferable. Examples of the metal used in the electroless plating bath include copper, tin, lead, nickel, gold, silver, palladium, and rhodium. Among them, from the viewpoint of superior conductivity of the metal wiring, copper, silver, or gold is preferable and copper is more preferable. Further, an optimal reducing agent and an optimal additive are selected according to the metal.

The immersion time in the electroless plating bath is preferably 1 minute to 6 hours and more preferably 1 minute to 3 hours.

In the case where a plating catalyst or a precursor thereof applied to the plated layer has a function as an electrode, electrolytic plating can be carried out on the plated layer to which the catalyst or the precursor thereof has been applied.

As described above, in the present step, if necessary, an electrolytic plating treatment may be carried out after the electroless plating treatment. In such an aspect, the thickness of a metal wiring to be formed is appropriately adjustable.

A method known in the related art can be mentioned as a method of electrolytic plating. Examples of the metal used in electrolytic plating include copper, chromium, lead, nickel, gold, silver, tin, and zinc. From the viewpoint of superior conductivity of the metal wiring, copper, gold, or silver is preferred and copper is more preferred.

### Metal Wiring-Containing Laminate

According to the method described above, a metal wiring-containing laminate (electroconductive film) including a substrate, a plated layer disposed on the substrate and having a groove portion and a functional group capable of interacting with a plating catalyst or a precursor thereof, and a metal wiring disposed so as to fill the groove portion of the plated layer can be obtained.

Metals are scattered on the surface of the plated layer of the metal wiring-containing laminate opposite to the substrate side. More specifically, metals are scattered on the surface 18a of the plated layer 18 opposite to the substrate 10 shown in FIG. 5. As these metals, metals derived from the plating catalyst or the precursor thereof applied to the plated layer in the foregoing Step C can be mentioned. It is preferred that the type of the metals scattered on the surface of the plated layer opposite to the substrate side is different from that of the metals constituting the metal wiring.

One suitable aspect of the metal wiring-containing laminate may be, for example, an aspect in which metals of the same type as the metals scattered on the surface of the plated layer opposite to the substrate side are scattered on the side wall surface of the groove portion of the plated layer, and the amount of the metals scattered on the side wall surface of the groove portion of the plated layer is larger than the amount of the metals scattered on the surface of the plated layer opposite to the substrate side.

As described above, in the plated layer used in Step C, the plating catalyst or the precursor thereof tends to be adsorbed on the side wall surface of the groove portion more than the surface thereof. As a result, there is a difference in the amount of metals as described above.

The width of the metal wiring in the metal wiring-containing laminate is not particularly limited, but it is preferably 10 μm or less, more preferably 5 μm or less, and still more preferably 2 μm or less from the viewpoint of miniaturization. The lower limit thereof is not particularly limited, but it is often 0.005 μm or more in many cases.

### Applications

The metal wiring-containing laminate can be applied to various uses, examples thereof include various applications such as a touch panel (or a touch panel sensor), a semiconductor chip, various electric wiring boards, a flexible printed circuit (FPC), a chip on film (COF), a tape automated bonding (TAB), an antenna, a multilayer wiring board, a fingerprint detection electrode of a fingerprint authentication device, and a mother board. Among them, it is preferable to use such a laminate for a touch panel sensor (electrostatic capacitance touch panel sensor). In the case where the metal wiring-containing laminate is applied to a touch panel sensor, the metal wiring in the metal wiring-containing laminate functions as a detection electrode or a lead-out wiring in the touch panel sensor.

In the present specification, a combination of a touch panel sensor and various display devices (for example, a liquid crystal display device and an organic electroluminescence (EL) display device) is called a touch panel. The touch panel is preferably, for example, a so-called electrostatic capacitance touch panel.

### EXAMPLES

Hereinafter, the present invention will be described in more detail with reference to Examples. The materials, the use amounts, the ratios, the treatment contents, the treatment procedures, and the like shown in the following Examples can be appropriately changed without departing from the gist of the present invention. Therefore, the scope of the present invention should not be limitatively interpreted by the following Examples.

### Example 1

### Preparation of Plated Layer Forming Composition

Polyacrylic acid (viscosity: 8,000 to 12,000 cp (1cp=1 mPa·s), weight-average molecular weight: 370,000, manufactured by Wako Pure Chemical Industries, Ltd.) and tetrafunctional acrylamide A having the following structure (provided that R in the structural formula is hydrogen) were added at a solid content mass ratio of 6:4 in isopropanol to prepare a solution. Subsequently, an oxime-based polymerization initiator (IRGACURE OXE02, manufactured by BASF Japan Ltd.) was added to the above solution so that the content thereof was 5% by mass with respect to the tetrafunctional acrylamide A described above. Next, W-AHE (manufactured by FUJIFILM Corporation) as a surfactant was added to the solution to which the oxime-based polymerization initiator had been added so that the concentration thereof was 0.02% by mass with respect to the total mass of the composition, thereby preparing a plated layer forming composition.

Tetrafunctional acrylamide A (see the following structural formula where R represents a hydrogen atom)

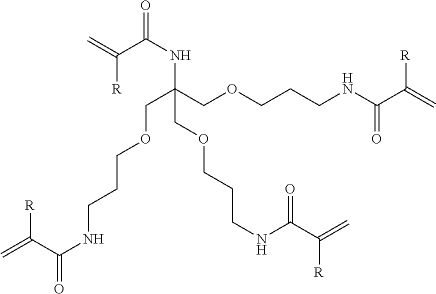

The plated layer forming composition was bar-coated on an easily adhesive layer of a polyethylene terephthalate (PET) film with an easily adhesive layer (LUMIRROR U48, manufactured by Toray Industries, Inc.). The PET film coated with the plated layer forming composition was dried at 80° C. for 2 minutes to form a photosensitive layer (thickness: about 0.5 μm) on the PET film.

Next, under vacuum, the photosensitive layer was subjected to ultraviolet (UV) irradiation (energy amount: 7.5 J, 14 mW, wavelength: 254 nm) through a photo mask having a mesh pattern with a mask width (width of light shielding portion, corresponding to W in FIG. 4) of 0.9 μm. The UV-irradiated photosensitive layer was developed with water to obtain a plated layer having a groove portion in a mesh pattern shape.

The UV irradiation was carried out in a state in which the photo mask was in close contact with the photosensitive layer.

Next, the PET film having a plated layer thus obtained was washed with water, and then the PET film was immersed in a Pd catalyst-applying liquid (manufactured by R&H Co., Ltd.) at 30° C. for 5 minutes. Next, the PET film taken out from the Pd catalyst-applying liquid was washed with water, and then the PET film was immersed in a metal catalyst-reducing liquid (manufactured by R&H Co., Ltd.) at 30° C. Next, the PET film taken out from the metal catalyst-reducing liquid was washed again with water, and then the PET film was immersed in a copper plating liquid (manufactured by R&H Co., Ltd.) at 30° C. for 15 minutes to produce a metal wiring-containing laminate in which a metal wiring was formed so as to fill a mesh pattern-like groove portion.

### Example 2

A metal wiring-containing laminate was produced in the same manner as in Example 1, except that the mask width of the photo mask was changed from 0.9 μm to 1.5 μm.

### Example 3

A metal wiring-containing laminate was produced in the same manner as in Example 1, except that the mask width of the photo mask was changed from 0.9 μm to 2 μm.

### Example 4

A metal wiring-containing laminate was produced in the same manner as in Example 1, except that the mask width of the photo mask was changed from 0.9 μm to 4 μm.

The metal Pd was scattered on the surface of the plated layer of the metal wiring-containing laminate obtained in Examples 1 to 4 opposite to the substrate side.

Further, the metal Pd was also scattered on the side wall surface of the groove portion of the plated layer of the metal wiring-containing laminate obtained in Examples 1 to 4.

### EVALUATION

### Evaluation of Metal Concentration

A cross-sectional scanning electron microscope (SEM) photograph of the metal wiring in the resulting metal wiring-containing laminate was taken and metal Pd concentrations in the side wall surface portion and the surface portion were evaluated according to the following standards. Preferred is “A”.

“A”: The metal Pd concentration in the side wall surface portion/metal Pd concentration in the surface portion is more than 1

“B”: The metal Pd concentration in the side wall surface portion/metal Pd concentration in the surface portion is 1 or less

### Evaluation of Resistance

The resistance value of the metal wiring in the resulting metal wiring-containing laminate was measured by LORESTA MCP-T610 (manufactured by Mitsubishi Chemical Analytech Co., Ltd.) and evaluated according to the following standards. For practical use, preferred is “A”.

“A”: The resistance value is less than 100Ω/□

“B”: The resistance value is 100Ω/□ or more

### Evaluation of Thinning

The width of the metal wiring in the resulting metal wiring-containing laminate was observed under SEM and evaluated according to the following standards. For practical use, preferred is “A”.

“A”: In the case where the width of the metal wiring is a width within the mask width+0.1 μm

“B”: In the case where the width of the metal wiring is a width greater than the mask width+0.1 μm

The above results are summarized in Table 1 below.

TABLE 1

| | | Evaluation | | |
|---|---|---|---|---|
| | | Evaluation of | Evaluation | |
| | Mask width | metal | of | Evaluation of |
| | (μm) | concentration | thinning | resistance |
| Example 1 | 0.9 | A | A | A |
| Example 2 | 1.5 | A | A | A |
| Example 3 | 2 | A | A | A |
| Example 4 | 4 | A | A | A |

As shown in Table 1 above, according to the production method of the present invention, it was possible to efficiently produce a metal wiring-containing laminate having a fine low-resistance metal wiring.

### EXPLANATION OF REFERENCES

10: substrate

12: photosensitive layer

14: light shielding portion

16: groove portion

18: plated layer

18a: surface

18b: side wall surface

20: lattice

22: metal wiring

What is claimed is:

1. A method for producing a metal wiring-containing laminate, comprising:
a step of forming a photosensitive layer having a functional group capable of interacting with a plating catalyst or a precursor thereof on a substrate;
a step of exposing the photosensitive layer in a patternwise manner and subjecting the exposed photosensitive layer to a development treatment to form a plated layer having a groove portion;
a step of applying a plating catalyst or a precursor thereof to the plated layer; and
a step of subjecting the plated layer, to which the plating catalyst or the precursor thereof has been applied, to a plating treatment to form a metal wiring so as to fill the groove portion.

2. The method for producing a metal wiring-containing laminate according to claim 1,
wherein the photosensitive layer is a negative tone photosensitive layer, and
the photosensitive layer is exposed through a photo mask having a light shielding portion having a width of 10 μm or less at the time of exposure.

3. The method for producing a metal wiring-containing laminate according to claim 1, wherein the photosensitive layer contains a compound having a functional group capable of interacting with a plating catalyst or a precursor thereof, and a compound having a polymerizable group.

4. A metal wiring-containing laminate, comprising:
a substrate;
a plated layer disposed on the substrate and having a groove portion and a functional group capable of interacting with a plating catalyst or a precursor thereof; and
a metal wiring disposed so as to fill the groove portion of the plated layer,
wherein metals are scattered on a surface of the plated layer opposite to the substrate side.

5. The metal wiring-containing laminate according to claim 4,
wherein metals of the same type as the metals scattered on the surface of the plated layer opposite to the substrate side are scattered on a side wall surface of the groove portion of the plated layer, and
the amount of the metals scattered on the side wall surface of the groove portion of the plated layer is larger than the amount of metals scattered on the surface of the plated layer opposite to the substrate side.

6. A substrate with a plated layer, comprising:
a substrate; and
a plated layer disposed on the substrate and having a groove portion and a functional group capable of interacting with a plating catalyst or a precursor thereof.

7. The method for producing a metal wiring-containing laminate according to claim 2, wherein the photosensitive layer contains a compound having a functional group capable of interacting with a plating catalyst or a precursor thereof, and a compound having a polymerizable group.
